(19) United States
(12) Patent Application Publication
(10) Pub. No.: US 2008/0090393 A1
(43) Pub. Date: Apr. 17, 2008

(54) ULTRA SHALLOW JUNCTION WITH RAPID THERMAL ANNEAL

(76) Inventors: Wolfgang Aderhold, Cupertino, CA (US); Susan B. Felch, Los Altos Hills, CA (US)

Correspondence Address: PATTERSON & SHERIDAN, LLP, 3040 POST OAK BOULEVARD, SUITE 1500, HOUSTON, TX, 77056, US

(21) Appl. No.: 11/867,748

(22) Filed: Oct. 5, 2007

Related U.S. Application Data
(60) Provisional application No. 60/828,947, filed on Oct. 10, 2006.

(51) Int. Cl. H01L 21/265

(52) U.S. Cl. 438/530; 257/E21.334

(57) ABSTRACT

Embodiments of the invention generally provide a method for forming an ultra shallow junction in a semiconductor device. In one embodiment, the method includes providing a silicon containing layer disposed on a substrate, implanting carbon and an elemental dopant into the silicon containing layer on the substrate, and annealing the implanted silicon containing layer. In another embodiment, the method includes providing a silicon containing layer on a substrate, implanting carbon and an elemental dopant into the silicon containing layer to form source and drain regions on the substrate, annealing the silicon containing layer, and forming an ultra shallow junction between the source and drain regions on the substrate having a junction depth less than 20 nm.

### RELATED APPLICATIONS

This application claims benefit of U.S. Provisional Patent Application Ser. No. 60/828,947, filed Oct. 10, 2006, which is incorporated by reference in its entirety.

### BACKGROUND OF THE INVENTION

1. Field of the Invention

Embodiments of the invention generally relate to the field of semiconductor manufacturing processes, and more particular, to methods of forming ultra shallow junction having reduced junction depths and improved dopant activation.

2. Description of the Related Art

A CMOS (complementary metal-oxide semiconductor) transistor includes a gate structure that is disposed between a source region and a drain region defined in a semiconductor substrate. The gate structure generally includes a gate electrode formed on a gate dielectric material. The gate electrode controls a flow of charge carriers, beneath the gate dielectric, in a channel region that is formed between a drain region and a source region, so as to turn the transistor on or off. The channel, drain, and source regions are collectively referred to in the art as a “transistor junction”. There is a constant trend to reduce dimensions of the transistor junction and decrease the channel region width in order to facilitate an increase in the operational speed of such transistors.

As smaller transistors are manufactured, ultra shallow junctions, low sheet resistance and abrupt lateral junctions are desired to reduce short channel effects and to increase transistor saturation current in source drain extensions. However, ultra shallow source/drain junctions are becoming more challenging to fabricate as junction depths of less than 40 nm for sub-100 nm CMOS devices are desired. Conventional doping by implantation followed by thermal post-annealing is often used to activate the dopants implanted in the substrate, and effectively remove implant damage. However, thermal post-annealing may often cause and/or aggravate dopant diffusion. Dopant diffusion may contaminate nearby layers and cause failure of the device.

Activating the dopants implanted in the source and drain regions with reduced junction depth, as well as high dopant activation is a major challenge for sub-micron front end of line (FEOL) processing. A tight balance exists between enhancing dopant activation and aggregating dopant diffusion. An aggressive activation anneal may lead to high carrier concentration, and the dopant may be driven into the channel region resulting in channel shorting. Insufficient thermal energy for dopant activation may result in lack of effective carrier chargers in the source/drain region, thereby leading to failure of the overall device performance.

Therefore, there is a need for having a process capable of forming ultra shallow junctions in a transistor with reduced junction depth, as well as, providing high dopant activation.

### SUMMARY OF THE INVENTION

Embodiments of the invention generally provide a method for forming an ultra shallow junction in a semiconductor device. In one embodiment, the method includes providing a silicon containing layer disposed on a substrate, implanting carbon and an elemental dopant into the silicon containing layer on the substrate, and annealing the implanted silicon containing layer.

In another embodiment, the method includes providing a silicon containing layer on a substrate, implanting carbon and an elemental dopant into the silicon containing layer to form source and drain regions on the substrate, annealing the silicon containing layer, and forming an ultra shallow junction between the source and drain regions on the substrate having a junction depth less than 20 nm.

In yet another embodiment, the method includes providing a silicon containing layer on a substrate, implanting carbon and an elemental dopant into the silicon containing layer to form source and drain regions on the substrate, annealing the silicon containing layer in an annealing chamber, cooling the substrate by removing heat absorbed by a highly emissive reflective plate disposed below the substrate in the annealing chamber at a rate in excess of 75 degrees Celsius per second, and forming an ultra shallow junction between the source and drain regions on the substrate having a junction depth less than 20 nm.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings.

FIG. 1 depicts a sectional perspective view of one embodiment of a thermal processing chamber having a reflector plate;

FIG. 2 depicts a process diagram illustrating a method for forming ultra shallow junction on a substrate;

FIGS. 3A-3D depicts cross sectional views of a semiconductor devices formed on a substrate at different stages of the method as described in FIG. 2; and

FIG. 4 depicts a Secondary Ions Mass Spectrometry (SIMS) graph illustrating phosphorus dopants dose and a junction depth profile with different annealing temperatures;

FIG. 5 depicts a Secondary Ions Mass Spectrometry (SIMS) graph illustrating boron dopants dose and a junction depth profile with different annealing temperature; and

FIG. 6 depicts a formed ultra shallow junction in a source and drain region in a substrate.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION OF THE PREFERRED EMBODIMENT

Embodiments of the invention provide methods for forming an ultra shallow junction in a transistor in a substrate. The ultra shallow junction in formed by ion implanting dopants into a silicon containing layer and followed by a rapid thermal annealing (RTA) process having a rapid temperature cool down rate after processing.

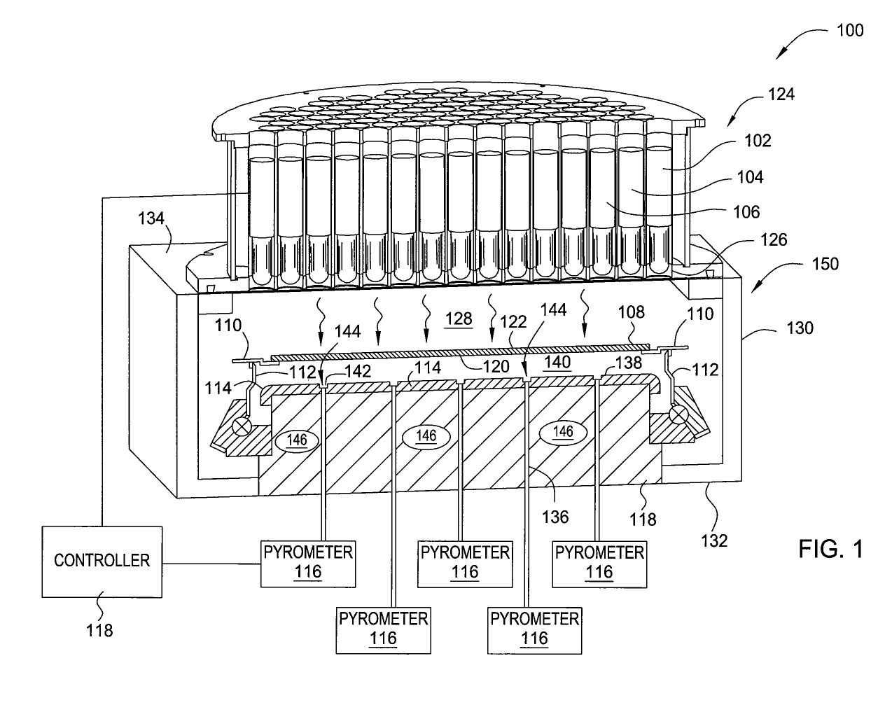

FIG. 1 depicts a simplified sectional perspective view of one embodiment of a rapid thermal processing chamber 100. Examples of rapid thermal processing chambers that may be adapted to benefit from the invention are XEplus and RadiancePlus™ CENTURA® thermal processing system, both available from Applied Material, Inc., located in Santa Clara, Calif. It is contemplated that other types of thermal processing system, including those from other manufactures, may also be utilized to perform the present invention.

The processing chamber 100 includes a chamber body 150 having chamber walls 130, a bottom 132, and a top 134 defining an interior volume 128. The walls 130 typically include at least one substrate access port (not shown) to facilitate entry and egress of a substrate 108.

A radiant heat assembly 124 is mounted to the top 134 of the chamber body 150. The radiant heat assembly 124 is utilized to heat the substrate 108 suspended by an edge ring 110 disposed around the periphery of the substrate 108. The radiant heat assembly 124 includes a plurality of lamp tubes 102 in a water jacket assembly 104. Each tube 102 contains a reflector and a tungsten halogen lamp assembly. The lamp tubes 102 are nested in a tight honeycomb pipe arrangement. This close-packed hexagonal arrangement of lamp tubes 102 provides radiant energy, such as an IR radiation and/or longer wavelength of UV radiation having a wavelength between about 400 nm and about 4000 nm, with high-power density. In one embodiment, the radiant heat assembly 124 provides radiant energy to thermally process the substrate, such as annealing a silicon layer disposed on the substrate 108. One radiant heat assembly 124 that may be adapted to benefit from the invention is described in U.S. Pat. No. 5,487,127, issued Jan. 23, 1996 to Gronet, et al., and is hereby incorporated by reference in its entirety.

The edge ring 110 that supports substrate 108 is spaced above a stainless steel base 118 by a rotatable quartz cylinder 112 mounted on a stainless steel base 118. The edge ring 110 may be fabricated from a hard material with a small coefficient of thermal expansion, such as silicon carbide, to prevent excessive expansion and contraction during thermal processing. The quartz cylinder 112 is rotated between about 50 rpm and about 300 rpm during substrate processing to maximize substrate temperature uniformity by minimizing the effect of thermal asymmetries in the chamber 100 and on the substrate 108. In one embodiment, the cylinder 112 may be coated with silicon to render the cylinder opaque to a desired wavelength. The base 118 has a circulation circuit 146 allowing coolant, such as water, to circulate therethrough. The coolant circulation efficiently cools down the chamber temperature after processing.

A reflector plate 114 is disposed below the substrate 108 and mounted above the base 118. An array of temperature probes 144 is embedded in the reflector plate 114 through openings 142 defined therein. The temperature probes 144 are connected to pyrometers 116 through a conduit 136 that extends from the bottom side of the base 118 to the openings 142 in the reflector plate 114. The temperature probes 144 and pyrometers 116 are used to obtain a metric indicative of temperatures of regions of the substrate 108 proximate each probe 144 such that a temperature gradient of the substrate may be determined.

The bottom side 120 of the substrate 108 and the upper side 138 of the reflector plate 114 bound a reflecting cavity 140 therebetween. The reflecting cavity 140 enhances the effective emissivity of the substrate 108, thereby improving the accuracy of the temperature measurement. A controller 118 may receive measurements from the pyrometers 116 and output control signals to radiant heat assembly 124 for real-time modify the radiation generated in the processing chamber 100, thereby maintaining the substrate temperature within a desired processing range.

The upper side 138 of the reflector plate 114 is highly reflective, and reflects thermal radiation in a target wavelength range and absorbs thermal radiation other then the target wavelength range. One or more coating or layers may be utilized to coat the reflector plate 114 on the base 118 to provide the selective reflectivity. For example, different combination of coatings with different reflectivity and absorbability may be utilized to enable the reflector plate 114 to reflect thermal radiation at a desired wavelength back to the substrate 108 and absorb (or less reflect) thermal radiation other than the desired wavelength. In one embodiment, the reflector plate 114 reflects the thermal wavelength between about 700 nm and about 1000 nm, and absorbs thermal wavelength below 700 nm and above 1000 nm. One reflector plate 114 that may be adapted to benefit from the invention is described in U.S. Pat. No. 6,839,507, issued Jan. 4, 2005 to Adams, et al., and is hereby incorporated by reference in its entirety.

The thermal energy not reflected to back to the substrate 108 is absorbed by the reflector plate 114. The absorbed thermal energy is efficiently and rapidly removed by the coolant circulating through the base 118 disposed below the reflector plate 114. Additionally, gas provided through holes (not shown) in the reflector plate 114 may be utilized to promote the cooling rate of the reflector plate 114 and the substrate 108 positioned thereabove. The rapid cool down rate provided by the reflector plate 114 promotes the temperature control of the substrate 108, thereby efficiently providing a desired temperature processing profile. In one embodiment, the reflector plate 114 may provide a substrate cool date rate greater than about 200 degrees Celsius per second. In another embodiment, the reflector plate 114 may provide a substrate cool date rate of about 220 degrees Celsius per second.

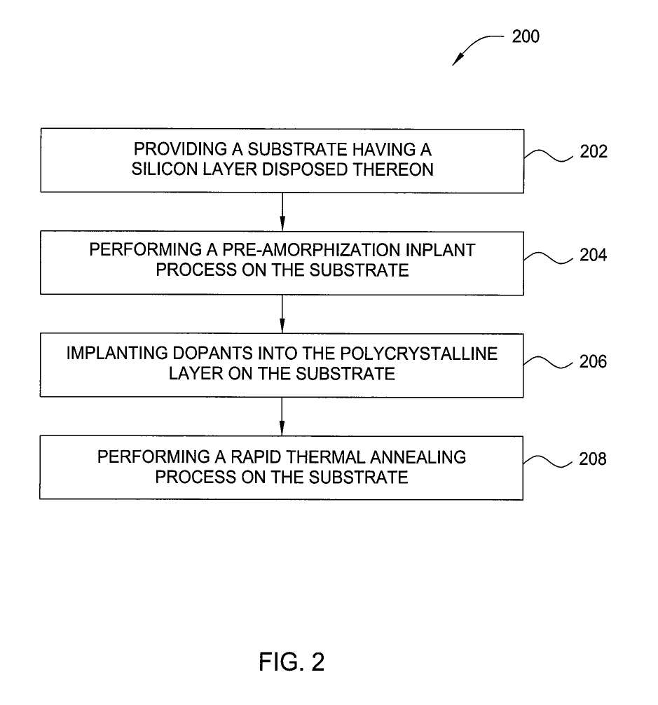

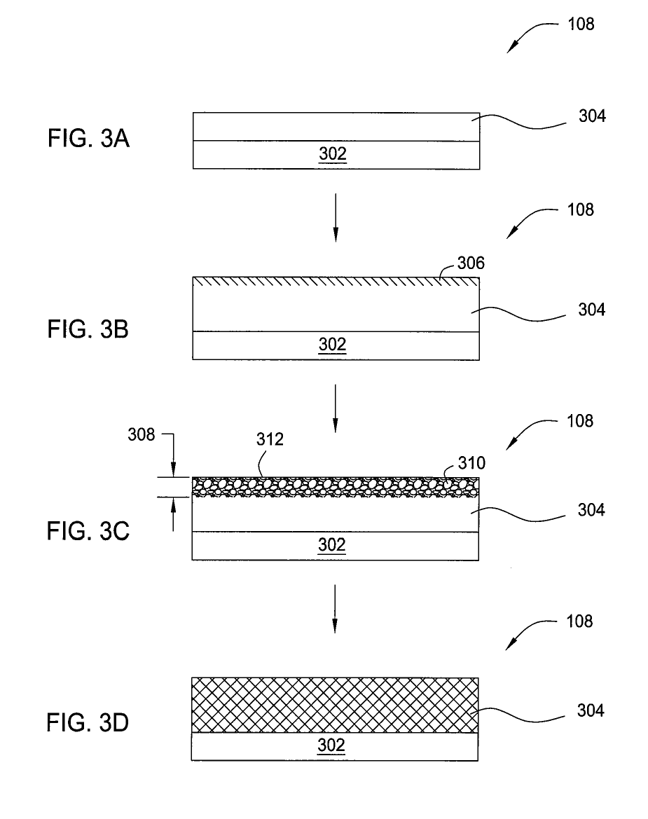

FIG. 2 depicts a process flow diagram of a method 200 for forming a ultra shallow junction in a semiconductor device in a substrate. FIG. 3A-3D are schematic cross-sectional view illustrating a substrate utilized to form the shallow junction.

The method 200 begins at step 202 by providing a substrate 108 utilized to form semiconductor devices, as shown in FIG. 3A. In the embodiment depicted in FIG. 3A, the substrate 108 includes a base layer 302 having a silicon layer 304 formed thereon. The silicon layer 304 may be a polycrystalline silicon, a doped or undoped polysilicon layer or a crystalline silicon. The base layer 302 may be a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), doped silicon, germanium, gallium arsenide, glass, and sapphire. The base layer 302 may have various dimensions, such as 200 mm or 300 mm diameter wafers, as well as, rectangular or square panes. In embodiments that the silicon layer 304 is not present, the process steps may be performed on the base layer 302 directly. The substrate 302 and the silicon layer 304 may be cleaned before the subsequent processes as described below performed thereon.

At step 204, an optional pre-amorphization implant (PAI) process is performed. The pre-amorphization implant (PAI) process provides dopants implanted into the silicon layer 304 with a limit implant depth 306, as shown in FIG. 3B. Ions are implanted into the silicon layer 304 in a sufficient dose to disrupt the crystal lattice structure of the silicon layer 304 so the silicon layer becomes amorphous. The pre-amorphization implant (PAI) process may be performed with a desired dopant, dose, and energy, and under a desired implant angle. Examples of dopants includes Ge, Xe, Sb, Si and Ar. Ion implantation apparatus that may be utilized to perform the implantation process include the Quantum III® system and the PRECISION IMPLANT 9500 XR LEAP® system, both available from Applied Materials Inc., Santa Clara, Calif. Other systems may also be utilized.

In one embodiment, the ion implantation process may be performed at an implantation energy of between about 2 and about 20 KeV and a dose from about 1×10¹³ atoms/cm² to about 1×10¹⁵ atoms/cm² at angle between 0 degree and 45 degrees. For example, the ion implantation process may be performed at an implantation energy of about 20 KeV and a dose of Ge element from about 5×10¹⁴ atoms/cm². Exemplary details of the dopants implanted by the ion implantation process are described in commonly assigned, U.S. Pat. No. 6,583,018, which is incorporated herein by reference.

At step 206, an ion implantation process is performed on substrate 108 to implant the elements into the silicon layer 304. FIG. 3C depicts elemental dopants 310 implanted into a desired depth 308 of the silicon layer 304 which may be later utilized to form a desired profile of a source and drain region for a semiconductor device. The elemental dopants may be selected by a Group III, Group IV element, or other types of elements with a combination of carbon or fluorine element. For example, the elemental dopants may include boron, arsenic, phosphorous, gallium, antimony, indium, fluorine, or combination thereof, and a combination of carbon or fluorine element. The carbon or fluorine elements co-implanted with the elemental dopants assist to trap the interstitials of the silicon elements in the silicon layer 304 by substitutional carbon or fluorine, thereby efficiently reducing the dopant diffusion that may occur during subsequent thermal annealing process, and, thus, reducing junction depth and lateral length.

The elemental dopant implanted along with the carbon or fluorine elements may have a dose in a range from about 1×10¹³ atoms/cm² to about 1×10¹⁶ atoms/cm². In one example, the silicon layer 304 may be doped as P type having a co-implantation of carbon and boron to a dose in a range from 1×10¹³ atoms/cm² to about 1×10¹⁵ atoms/cm², such as about 1×10¹⁵ atoms/cm² for carbon and about 7×10¹⁴ atoms/cm² for boron. The implantation energy may be performed of between about 0.1 and about 10 KeV. For example, the implantation energy may be performed about 4 KeV for carbon element implantation and about 2 KeV for boron element implantation. In another example, the silicon layer 304 may be doped as N type, having a co-implantation of carbon and phosphorus to a dose in a range from 1×10¹³ atoms/cm² to about 1×10¹⁵ atoms/cm², such as about 1×10¹⁵ atoms/cm² for carbon and about 7×10¹⁴ atoms/cm² for phosphorus. The implantation energy may be performed of between about 0.1 and about 10 KeV. For example, the implantation energy may be performed about 6 KeV for carbon element implantation and about 1 KeV for phosphorus element implantation.

At step 208, a rapid thermal annealing process is performed to activate the dopants implanted in the silicon layer 304. The rapid thermal annealing process may be performed in the thermal annealing chamber 100, as described in FIG. 1.

The silicon layer 304 implanted by the dopants is exposed to the thermal annealing process to redistribute the implanted dopants and increase the dopant dose in favorable lattice sites in the silicon layer 304. Atom sites with the crystalline lattice of the silicon layer 304 are opened to incorporate the incoming carbon and dopant atoms, thereby efficiently activating the dopants implanted in the silicon layer 304. As most of the dopants may be substantially activated after a predetermined process period, by utilizing the fast cooling rate of the reflector plate 114, the rapid temperature drop of the substrate 108 causes the dopants to stay and occupy in the desired lattice sites without further diffusing into undesired location and/or into adjacent materials. In one embodiment, the substrate 108 may be cooled down by the reflector plate 144 at a rapid rate greater than 75 degrees Celsius per second, such as greater than 150 degrees Celsius per second, for example, greater than 200 degrees Celsius per second.

In one embodiment, the thermal annealing process is performed by a rapidly annealing the substrate 108 between about 2 second and 50 seconds while maintaining substrate temperature between about 900 degrees Celsius and about 1100 degrees Celsius prior to rapid cooling. In one example, the thermal annealing process may be performed for about 40 seconds at a substrate temperature of between about 950 degrees Celsius and about 1050 degrees Celsius.

In another example, the thermal annealing process may be performed by two step annealing process followed by rapid cooling. The substrate temperature is initially raised to about 550 degrees Celsius for about 30 seconds to stabilize the substrate 108 and chamber temperature until the substrate 108 has been thoroughly heated to the desired temperature. Subsequently, the substrate temperature is further ramped up in a second step to a predetermined temperature between about 900 degrees Celsius and about 1100 degrees Celsius. For example, the substrate temperature may be ramped up to at least about 950 degrees Celsius, about 1000 degrees Celsius, or about 1050 degrees Celsius. The temperature of the second step may be based on specific process requirement. The ramp up rate of the substrate temperature may be set at between about 200 degrees Celsius per second and about 300 degrees Celsius per second, such as 220 degrees Celsius per second. It is noted that the annealing process, including process time and temperature, may be varied based on the elemental dopants and dopant dose present.

After the thermal annealing process is completed, the carbon and doped elementals are thoroughly distributed in the silicon layer 312, as shown in FIG. 3D. Furthermore, after the thermal annealing process, a laser thermal annealing process, such as a dynamic surface annealing (DSA) process, may be performed to further active dopants as needed.

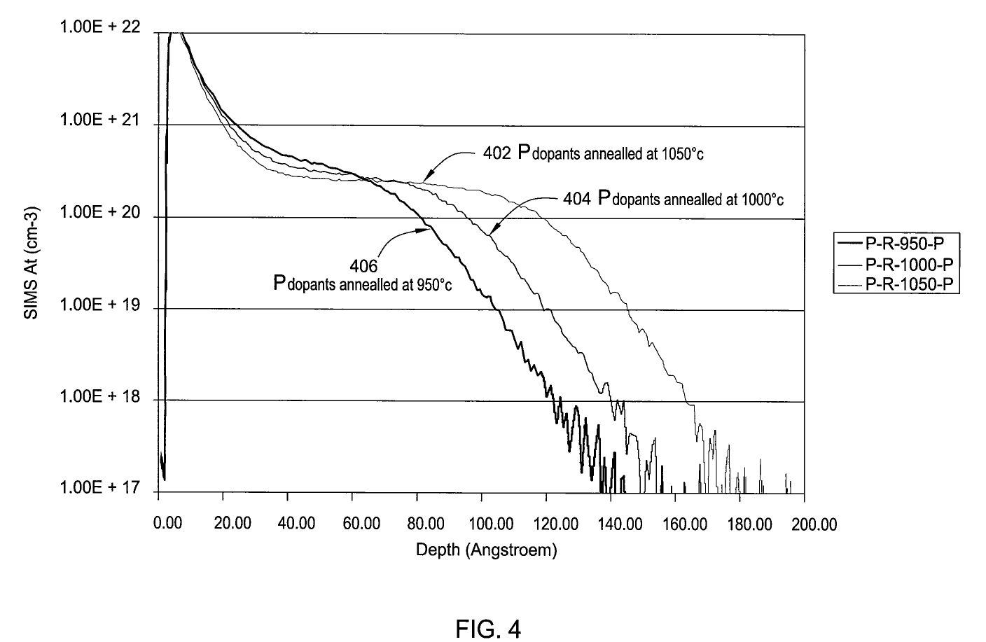

FIG. 4 depicts an Ions Mass Spectrometry (SIMS) graph illustrating phosphorus dopant dose and a junction depth profile of structures formed with different annealing temperatures. In embodiment depicted in FIG. 4, the silicon layer is processed by a Ge pre-amorphization and implanted by carbon with a dose about 1×10¹⁵ atoms/cm² and phosphorous about 7×10¹⁴ atoms/cm². The phosphorus implanted silicon layer is subsequently annealed with different temperature at about 950 degrees Celsius, about 1000 degrees Celsius, and about 1050 degrees Celsius, as shown by reference numeral 406, 404 and 402 respectively. The X-axis represents the penetrating depth of the phosphorus dopants implanted in the silicon layer. The Y-axis represents the phosphorus dopant dose profile remained in the different penetrating depth in the silicon layer. The phosphorus implanted silicon layer processed at different temperature has a diffusion length less than 20 nm (200 Å) with a dose about 1×10¹⁷ atoms/cm². As compared to the conventional dopant profile, a trailing long diffusion depth up to 45 nm with significant low dopant dose is often found. The phosphorus implanted silicon layer processed at about 950 degree Celsius 406 as described in the present invention has a short diffusion length about 6 nm (60 Å) while having a high dose of about 5×10²⁰ atoms/cm².

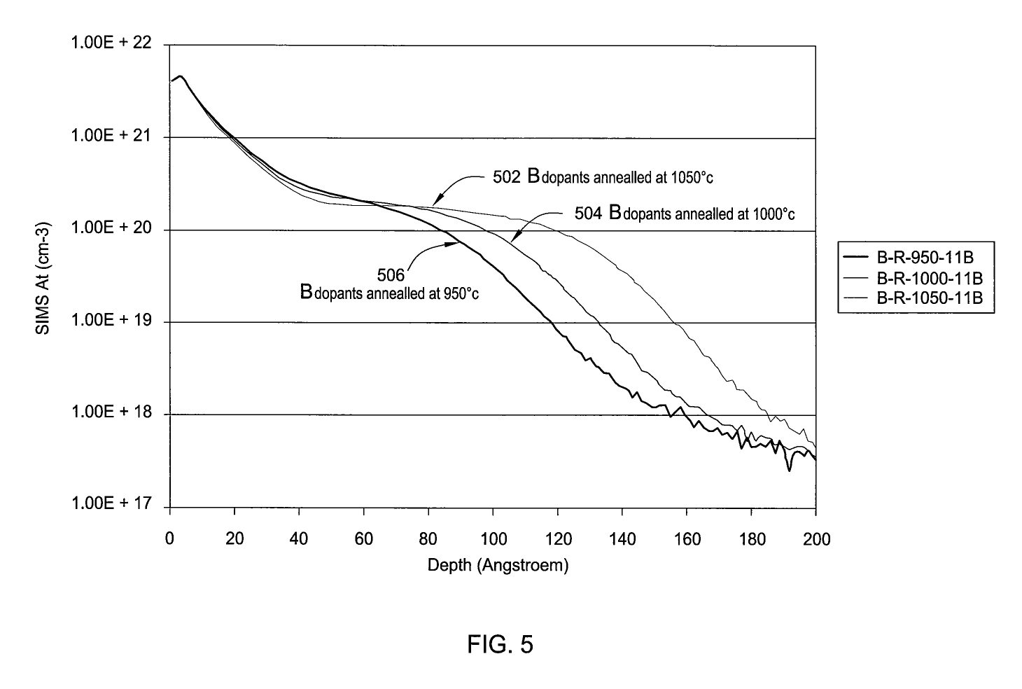

FIG. 5 depicts Ions Mass Spectrometry (SIMS) graph illustrating boron dopant dose and a junction depth profiles of structures formed with different annealing temperatures. In embodiment depicted in FIG. 5, the silicon layer is processed by a Ge pre-amorphization and implanted by carbon with a dose about 1×10¹⁵ atoms/cm² and boron about 7×10¹⁴ atoms/cm². The boron implanted silicon layer is subsequently annealed with different temperature at about 950 degrees Celsius, about 1000 degrees Celsius, and about 1050 degrees Celsius, as shown by reference numeral 506, 504 and 202 respectively as described in FIG. 4. Similar to the diffusion behavior as described in FIG. 4, the boron implanted silicon layer processed at different temperature has a diffusion length less than 20 nm (200 Å) with a dose about 1×10¹⁷ atoms/cm². The boron implanted silicon layer processed at about 950 degree Celsius 506 has a short diffusion length about 6 nm (60 Å) while having a high dose of about 2×10²⁰ atoms/cm².

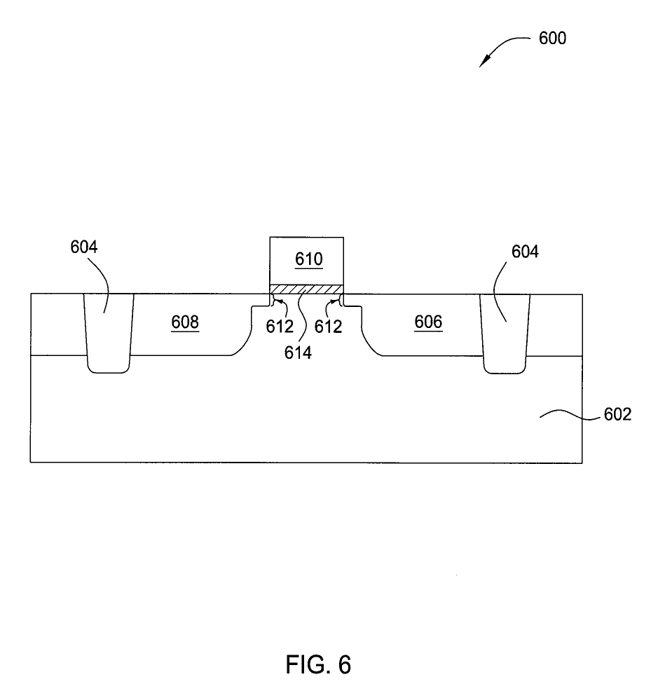

FIG. 6 depicts a source and drain region with dopants activated by an annealing process as described above having a desired ultra shallow junction formed therein. The substrate 602 has at least one partially formed semiconductor device 600 disposed thereon. Shallow trench isolations (STI) 604 are present to isolate each semiconductor device 600 formed on the substrate 602. One device 600 and two STI's 604 are shown in FIG. 6. A polysilicon gate electrode 610 is formed on a gate dielectric layer 614 disposed on the substrate 602. Source 608 and drain 606 regions are formed adjacent the gate dielectric 614 in the substrate 602 by ion implantation with the dopants as discussed above below. As the thermal annealing process performed on the substrate 602 with the rapid cool down rate provided by the processing chamber 100, the source 608 and drain 606 regions with the implanted dopants provides a desired ultra shallow junction with a minimum depth 612 less than about 20 nm.

Thus, methods for forming an ultra shallow junction in semiconductor devices are provided in the present invention. The ultra shallow junction is achieved by performing thermal annealing process on a substrate having a selected combination of dopants implanted therein in a chamber. The chamber provides a rapid cool date rate, thereby eliminating dopant diffusion on the substrate and increasing overall dopant dose in the devices with minimum dopant diffusion length as well as high dopant activation.

While the foregoing is directed to embodiments of the invention, other and further embodiments of the invention may be devised without departing from the basic scope thereof, and the scope thereof is determined by the claims that follow.

1. A method for forming an ultra shallow junction in a semiconductor device on a substrate, comprising:
providing a silicon containing layer disposed on a substrate;
implanting carbon and an elemental dopant into the silicon containing layer on the substrate; and
annealing the implanted silicon containing layer.

2. The method of claim 1, wherein the step of implanting further comprises:
forming a source and drain regions in the substrate.

3. The method of claim 2, further comprising:
forming an ultra shallow junction between the source and drain regain having a junction depth less than 20 nm.

4. The method of claim 1, wherein the step of implanting further comprises:
implanting carbon and the elemental dopant with a dopant dose of about 1×10^{13 atoms/cm}² to about 1×10¹⁶.

5. The method of claim 1, wherein the elemental dopant is selected from a group consisting of boron, arsenic, phosphorous, gallium, antimony, indium and fluorine.

6. The method of claim 1, wherein the step of annealing further comprises:
heating the substrate to a temperature between about 900 degrees Celsius and about 1100 degrees Celsius.

7. The method of claim 1, wherein the step of annealing further comprises:
heating the substrate to a temperature of about 950 degrees Celsius.

8. The method of claim 1, wherein the step of annealing further comprises:
heating the substrate in an annealing chamber; and
rapidly cooling the heated substrate by removing heat from a highly emissive reflector plate disposed below the substrate.

9. The method of claim 8, wherein the reflector plate reflects thermal radiation having a wavelength between about 700 nm to about 1000 nm.

10. The method of claim 8, wherein the reflector plate absorbs thermal radiation having a wavelength above 1000 nm.

11. The method of claim 8, wherein the cooling the substrate further comprises:
cooling the substrate at a cooling rate greater than about 200 degrees Celsius per second.

12. The method of claim 1, wherein the step of implanting further comprises:
performing a pre-amorphization implant process to the silicon containing layer prior to implanting the carbon and elemental dopant.

13. The method of claim 12, wherein the step of performing a pre-amorphization implant process further comprises:
implanting Ge elemental dopants into the silicon containing layer.

14. The method of claim 13, wherein the step of implanting Ge elemental dopants further comprises:
implanting Ge elemental dopants to a dose of about 1×10¹³ atoms/cm² to about 1×10¹⁶ atoms/cm².

15. The method of claim 1, further comprising:
laser scan annealing the annealed substrate.

16. A method for forming an ultra shallow junction in a semiconductor device on a substrate, comprising:
providing a silicon containing layer on a substrate;
implanting carbon and an elemental dopant into the silicon containing layer to form source and drain region on the substrate;
annealing the silicon containing layer; and
forming an ultra shallow junction between the source and drain regions on the substrate having a junction depth less than 20 nm.

17. The method of claim 16, wherein the step of implanting further comprises:
performing a pre-amorphization implant process to the silicon containing layer disposed on the substrate prior to implanting the carbon and elemental dopant.

18. The method of claim 16, wherein the step of annealing further comprises:
heating the substrate to a temperature of about 950 degrees Celsius.

19. The method of claim 16, wherein the step of annealing further comprises:
cooling the substrate by removing heat absorbed by a highly emissive reflective plate disposed below the substrate.

20. A method for forming an ultra shallow junction in a semiconductor device on a substrate, comprising:
providing a silicon containing layer on a substrate;
implanting carbon and an elemental dopant into the silicon containing layer to form source and drain regions on the substrate;
annealing the silicon containing layer in an annealing chamber;
cooling the substrate by removing heat absorbed by a highly emissive reflective plate disposed below the substrate in the annealing chamber at a rate in excess of 75 degrees Celsius per second; and
forming an ultra shallow junction between the source and drain regions on the substrate having a junction depth less than 20 nm.
